(19) United States
(12) Patent Application Publication
(10) Pub. No.: US 2013/0104986 A1
(43) Pub. Date: May 2, 2013

(54) SOLAR CELLS AND METHODS OF MANUFACTURING THE SAME

(71) Applicants: Mi Hee JUNG, Daejeon (KR); Mangu Kang, Daejeon (KR)

(72) Inventors: Mi Hee JUNG, Daejeon (KR); Mangu Kang, Daejeon (KR)

(73) Assignee: ELECTRONICS AND TELECOMMUNICATIONS RESEARCH INSTITUTE, Daejeon (KR)

(21) Appl. No.: 13/452,242

(22) Filed: Apr. 20, 2012

(30) Foreign Application Priority Data
Oct. 26, 2011 (KR) 10-2011-0109756

(51) Int. Cl. H01L 31/0264; H01L 31/18; B82Y 40/00

(52) U.S. Cl. 136/260; 438/95; 136/253; 257/E31.032; 977/840

(57) ABSTRACT

Provided are solar cells and methods of manufacturing the same. The solar cell includes a first electrode, a second electrode facing and separated from the first electrode, and a quantum dot-graphine hybrid composite disposed between the first and second electrodes. Quantum dots are combined with graphine in a π-bond within the quantum dot-graphine hybrid composite.

### CROSS-REFERENCE TO RELATED APPLICATIONS

This U.S. non-provisional patent application claims priority under 35 U.S.C. §119 to Korean Patent Application No. 10-2011-0109756, filed on Oct. 26, 2011, the entirety of which is incorporated by reference herein.

### BACKGROUND

The inventive concept relates to solar cells and methods of manufacturing the same and, more particularly, to quantum dot solar cells and methods of manufacturing the same.

Dye-sensitized solar cells (DSSCs) were developed by Prof. M. Gratzel in 1991. Recently, the DSSCs have generating efficiency of about 11% or more and are become more and more commercialized. Large-scaled modules of the DSSCs have already been commercialized in Japan and Germany. However, when electrons generated by light pass through a TiO₂ layer, a charge recombination phenomenon occurs, so that characteristic of the DSSCs may be deteriorated. For preventing the charge recombination phenomenon and improving electron-transporting capacity, various researches have been conducted. For example, a metal oxide hybrid composite body with different band-gaps may be used, a porous structure may be formed in a direction vertical to a conductive substrate, and one-dimensional nano materials, which are electron transporters, may be used in an electron transmission direction. Solar cells using quantum dot may not be sufficiently developed at home and abroad. For example, a quantum dot of the 2-6 group compound semiconductor (e.g. CdS, PbS, CdTe, CdSe, InP) having a narrow band gap may be transmitted to a material (e.g. TiO₂, ZnO, SnO₂) having a wider band gap, so that an optical current of an ultraviolet region band may be generated. However, the efficiency of the quantum dot solar cells may be lowered due to corrosion of the quantum dot caused by an electrolyte and recombination of electron-hole.

### SUMMARY

Embodiments of the inventive concept may provide solar cells with low cost and high efficiency.

Embodiments of the inventive concept may also provide methods of manufacturing the solar cells.

According to embodiments of the inventive concept, a solar cell includes: a first electrode; a second electrode facing and separated from the first electrode; and a quantum dot-graphine hybrid composite disposed between the first and second electrodes. Quantum dots are combined with graphine in a π-bond within the quantum dot-graphine hybrid composite.

In some embodiments, the quantum dot-graphine hybrid composite may include cadmium selenide (CdSe)-graphine.

In other embodiments, the quantum dot-graphine hybrid composite may include: a first quantum dot-graphine including a quantum dot of a first size; and a second quantum dot-graphine including a quantum dot of a second size different from the first size. The quantum dot-graphine and the second quantum dot-graphine may be sequentially stacked.

In still other embodiments, the first and second electrodes may include a transparent and flexible material.

According to embodiments of the inventive concepts, a method of manufacturing a solar cell includes: preparing a first electrode; forming quantum dots combined with ligands; combining the quantum dots combined with ligands with graphine in a π-bond to form a quantum dot-graphine hybrid composite; depositing the quantum dot-graphine hybrid composite on the first electrode; and forming a second electrode on the quantum dot-graphine hybrid composite.

In some embodiments, forming the quantum dots combined with ligands may include: dissolving selenium in a solvent of phosphine series to form a first solution; dissolving cadmium in a solvent of phosphine series to form a second solution; and mixing the first solution into the second solution to form CdSe quantum dots combined with phosphine ligands.

In other embodiments, forming the CdSe quantum dots combined with phosphine ligands may include: heating the second solution; adding the first solution to the second solution for heating the second solution; and stopping heating the second solution when sizes of CdSe quantum dots become desired sizes.

In still other embodiments, forming the quantum dot-graphine hybrid composite may include: dispersing the CdSe quantum dots combined with the phosphine ligands and the graphine in pyridine; substituting pyridine ligands for the phosphine ligands to form CdSe quantum dots having the pyridine ligands; combining the CdSe quantum dots with the graphine in the π-bond to form a CdSe quantum dot-graphine hybrid composite including the pyridine ligands; and removing the pyridine ligands from the CdSe quantum dot-graphine hybrid composite including the pyridine ligands.

In yet other embodiments, forming the quantum dots combined with the ligands may include: preparing quantum dots combined with phosphine ligands; dispersing the quantum dots combined with phosphine ligands in a pyridine solution; and substituting pyridine ligands for the phosphine ligands to form quantum dots combined with the pyridine ligands.

In yet still other embodiments, the quantum dot-graphine hybrid composite may be formed on the first electrode by electrophoresis or a printing process.

In yet still other embodiments, forming the quantum dot-graphine hybrid composite further may include: substituting aniline ligands for the phosphine ligands of the CdSe quantum dots combined with the phosphine ligands, thereby forming CdSe quantum dots combined with the aniline ligands; and substituting benzyl diazonium cation ligands for the aniline ligands of the CdSe quantum dots combined with the aniline ligands, thereby forming CdSe quantum dots combined with the benzyl diazonium cation ligands.

In yet still other embodiments, forming the quantum dot-graphine hybrid composite further may include: dispersing the graphine and the CdSe quantum dots combined with the benzyl diazonium cation ligands in a mixed solution of dimethyl formamide. NaNO₂ and HCl; and forming CdSe quantum dot-graph hybrid composite in the mixed solution by an electro-deposition process.

### BRIEF DESCRIPTION OF THE DRAWINGS

The inventive concept will become more apparent in view of the attached drawings and accompanying detailed description.

FIG. 1 is a perspective view illustrating a solar cell according to some embodiments of the inventive concept;

FIG. 2 is a cross-sectional view illustrating a solar cell according to other embodiments of the inventive concept;

FIG. 3 is a flow chart illustrating a method of manufacturing a solar cell according to some embodiments of the inventive concept;

FIG. 4A is a flow chart illustrating a method of manufacturing a solar cell according to other embodiments of the inventive concept;

FIG. 4B is a schematic diagram illustrating a method of manufacturing a solar cell according to other embodiments of the inventive concept.

FIG. 5 shows a molecule structural formula to explain chemical reaction of graphine formed by reducing graphine oxide and graphine combined with CdSe quantum dots;

FIGS. 6A and 6B are photographs of a surface graphine combined with CdSe quantum dots;

FIG. 6C is a graph illustrating components of graphine combined with CdSe quantum dots; and

FIG. 7 is a graph illustrating reaction of current density of a solar cell according to some embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

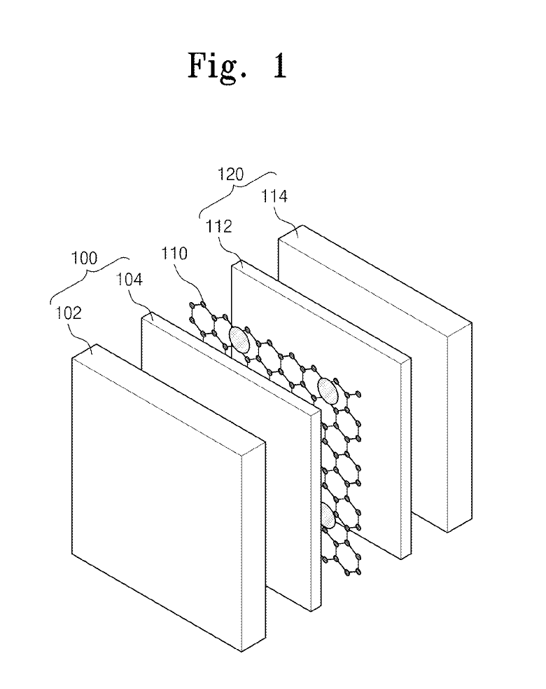

FIG. 1 is a perspective view illustrating a solar cell according to some embodiments of the inventive concept.

Referring to FIG. 1, a solar cell may include a first electrode 100, a second electrode 120 facing and separated from the first electrode 100, and a quantum dot-graphine hybrid composite 110 disposed between the first and second electrodes 100 and 120.

The first electrode 100 may function as a cathode of the solar cell.

The first electrode 100 may include a first substrate 102 and a first transparent-conductive thin layer 104. The first substrate 102 may be an organic substrate capable of transmitting light or a flexible polymer substrate capable of transmitting light. The first transparent-conductive thin layer 104 may be adhered to one surface of the first substrate 102. The first transparent-conductive thin layer 104 may be formed of an indium tin oxide (ITO) thin layer, a F-doped SnO2 (FTO) thin layer, or an ITO thin layer on which an antimony tin oxide (ATO) or a FTO is coated.

The quantum dot-graphine hybrid composite 110 may be deposited on one surface of the first transparent-conductive thin layer 104. According to some embodiments of the inventive concept, the quantum dot-graphine hybrid composite 110 may have cadmium selenide (CdSe) quantum dots which are combined with graphine in a π (pi)-bond. In some embodiments, the quantum dots combined with the graphine in the π-bond may have the same size as each other. In other embodiments, the quantum dots combined with the graphine in the π-bond may have various sizes different from each other.

The second electrode 120 may be disposed on one surface of the quantum dot-graphine hybrid composite 110. The second electrode 120 may include a second substrate 114 and a second transparent-conductive thin layer 112.

The second substrate 114 may be an organic substrate capable of transmitting light or a flexible polymer substrate capable of transmitting light. The second transparent-conductive thin layer 112 may be disposed on one surface of the second substrate 114. The second transparent-conductive thin layer 112 may be formed of an ITO thin layer, a FTO thin layer, or an ITO thin layer on which an ATO or a FTO is coated. The second electrode 120 may function as an anode of the solar cell.

A high cost dye of ruthenium series may be used in a conventional solar cell. However, according to some embodiments of the inventive concept, the solar cell including the quantum dot-graphine hybrid composite 110 uses the quantum dot of low cost and uses the graphine as a medium quickly transmitting electrons generated from the quantum dots. Thus, it is possible to reduce a manufacturing cost of the solar cell.

Additionally, since the quantum dot of the quantum dot-graphine hybrid composite 110 is combined with the graphine in the π-bond, a bonding force between the quantum dot and the graphine is stronger and density of the quantum dot and the graphine is higher. Thus, the electrons generated from the quantum dot may be easily and quickly moved.

Furthermore, since a single-layered quantum dot-graphine hybrid composite 110 may be formed on the first electrode 100 by one-step, it is possible to form a quantum dot-graphine hybrid composite structure including a plurality of the quantum dot-graphine hybrid composites 110 which are sequentially stacked. This will be described later.

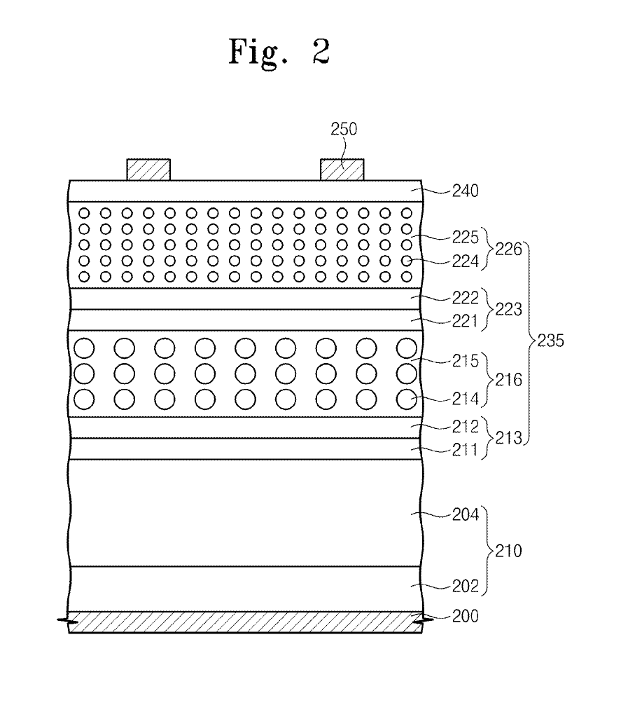

FIG. 2 is a cross-sectional view illustrating a solar cell according to other embodiments of the inventive concept.

Referring to FIG. 2, a solar cell according to the present embodiment may include a first electrode 200, a second electrode 250 facing and separated from the first electrode 200, and a quantum dot-graphine hybrid composite structure 235 disposed between the first and second electrodes 200 and 250.

The first electrode 200 may include metal such as aluminum. A silicon cell 210 may further be disposed on one surface of the first electrode 200. In some embodiments, the silicon cell 210 may have a multi-layered structure. The silicon cell 210 may include a first silicon layer 202 in contact with the one surface of the first electrode 210 and a second silicon layer 204 disposed on the first silicon layer 202. For example, the first silicon layer 202 may include a high concentration of P-type impurities and the second silicon layer 204 may include a low concentration of P-type impurities.

The quantum dot-graphine hybrid composite structure 235 may be disposed on the silicon cell 210. In some embodiments, the quantum dot-graphine hybrid composite structure 235 may include a plurality of quantum dot-hybrid composites 216 and 226 stacked in a vertical direction.

The quantum dot-graphine hybrid composite structure 235 may include a first quantum dot tunnel junction layer 213, a first quantum dot-graphine hybrid composite 216, a second quantum dot tunnel junction layer 223, and a second quantum dot-graphine hybrid composite 226.

The first quantum dot tunnel junction layer 213 may include a first layer 211 in contact with the silicon cell 210 and a second layer 212 disposed on the first layer 211. For example, the first layer 211 of the first quantum dot tunnel junction layer 213 may include N-type silicon and the second layer 212 of the first quantum dot tunnel junction layer 213 may include P-type silicon.

The first quantum dot-graphine hybrid composite 216 may be in contact with the second layer 212 of the first quantum dot tunnel junction layer 213. In some embodiments, the first quantum dot-graphine hybrid composite 216 may include quantum dots 214 having a first size. The intensity of light absorbed into the first quantum dot-graphine hybrid composite 216 may vary according to the size of the quantum dot 214 included in the first quantum dot-graphine hybrid composite 216. Additionally, the quantum dot 214 may be formed of cadmium selenide (CdSe) and the quantum dot 214 may be combined with graphine 215 in a π-bond.

The second quantum dot tunnel junction layer 223 may be disposed on the first quantum dot-graphine hybrid composite 216. The second quantum dot tunnel junction layer 223 may include a first layer 221 in contact with the first quantum dot-graphine hybrid composite 216 and a second layer 222 disposed on the first layer 221. For example, the first layer 221 of the second quantum dot tunnel junction layer 223 may include N-type silicon and the second layer 222 of the second quantum dot tunnel junction layer 223 may include P-type silicon.

The second quantum dot-graphine hybrid composite 226 may be in contact with the second layer 222 of the second quantum dot tunnel junction layer 223. In some embodiments, the second quantum dot-graphine hybrid composite 226 may include quantum dots 224 having a second size different from the first size. Since the size of the quantum dot 224 in the second quantum dot-graphine hybrid composite 226 is different from the size of the quantum dot 214 in the first quantum dot-graphine hybrid composite 216, the intensity of light absorbed into the second quantum dot-graphine hybrid composite 226 may be different from the intensity of the light absorbed into the first quantum dot-graphine hybrid composite 216. Additionally, the quantum dot 224 of the second quantum dot-graphine hybrid composite 226 may be formed of cadmium selenide (CdSe) and the quantum dot 224 may be combined with graphine 225 in a π-bond.

The solar cell may further include a quantum dot emitter 240.

The quantum dot emitter 240 may be in contact with the second quantum dot-graphine hybrid composite 226. For example, the quantum dot emitter 240 may include silicon doped with N-type impurities.

The second electrode 250 may be disposed on the quantum dot emitter 240. The second electrode 250 may function as an anode of the solar cell.

The second electrode 250 may have one of various shapes. In the present embodiment, the second electrode 250 may have a bar-shape extending in one direction, and the second electrode 250 may be provided in plural. The second electrode 250 may include metal such as aluminum.

The solar cell including the quantum dot-graphine hybrid composite structure 235 uses the quantum dots 214 and 224 of low cost differently from a conventional solar cell including a high cost dye of ruthenium series and uses the graphines 215 and 225 as mediums quickly transmitting electrons generated from the quantum dots 214 and 224. Thus, it is possible to reduce a manufacturing cost of the solar cell.

Additionally, since the quantum dots 214 and 224 of the quantum dot-graphine hybrid composite structure 235 are combined with the graphines 215 and 225 in the π-bond, bonding forces between the quantum dots 214 and 224 and the graphines 215 and 225 are stronger and densities of the quantum dots 214 and 224 and the graphines 215 and 225 are higher. Thus, the electrons generated from the quantum dots 214 and 224 may be easily and quickly moved.

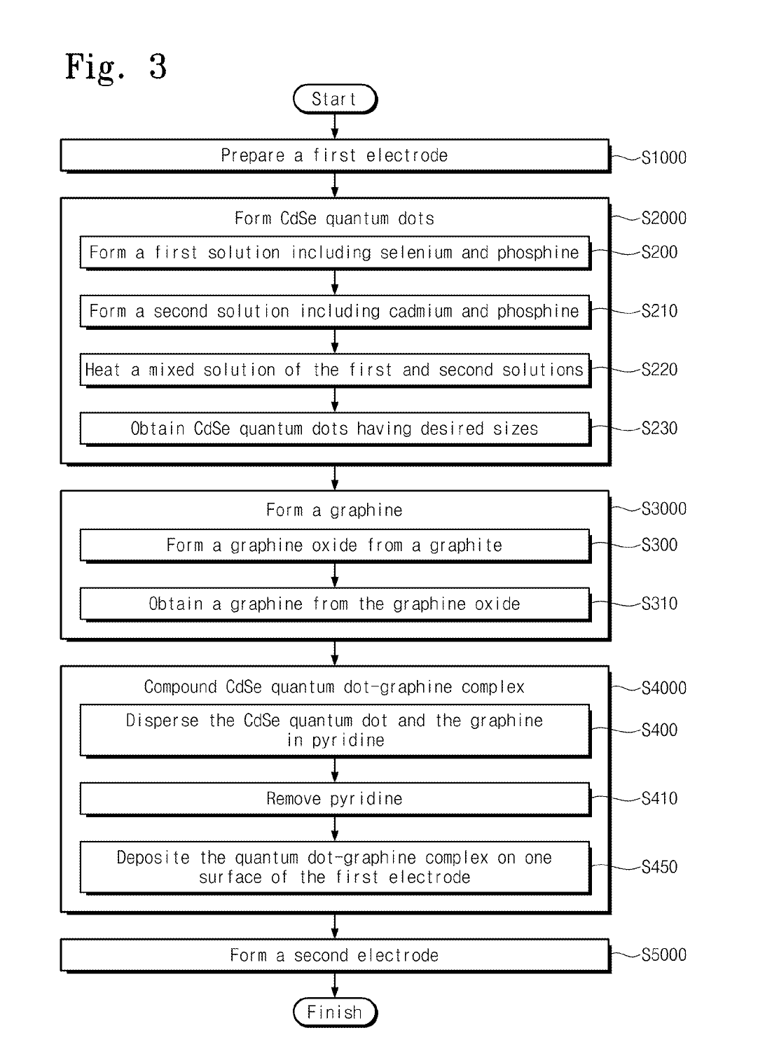

FIG. 3 is a flow chart illustrating a method of manufacturing a solar cell according to some embodiments of the inventive concept.

Referring to FIGS. 1 and 3, a first electrode 100 may be prepared (S1000). The first electrode 100 may include one surface and another surface opposite to the one surface.

A quantum dot-graphine hybrid composite 110 may be deposited on the first surface of the first electrode 100 (S4500). The method of forming the quantum dot-graphine hybrid composite 110 will be described in more detail hereinafter.

In some embodiments, the quantum dot-graphine hybrid composite 110 may be deposited on the first substrate 100 by electrophoresis. In more detail, the quantum dot-graphine hybrid composite 110 may be dispersed in tetrahydrofuran(THF). After the first electrode 100 may be put in the THF having the dispersed quantum dot-graphine hybrid composite 110, a DC power may be applied to the first electrode 100, thereby depositing the quantum dot-graphine hybrid composite 110 on the one surface of the first electrode 100.

Since the quantum dot-graphine hybrid composite 110 may be formed at a temperature lower than a temperature of a conventional art in solution state by the electrophoresis, the quantum dot-graphine hybrid composite 110 may have a substantially uniform thickness. Additionally, the quantum dot-graphine hybrid composite 110 deposited by the electrophoresis may be strongly combined with the first electrode 100.

In other embodiments, the quantum dot-graphine hybrid composite 110 may be deposited on the one surface of the first electrode 100 by a printing process. The printing process of the quantum dot-graphine hybrid composite 110 may be fit for mass production of the solar cell. Thus, it is possible to mass-produce the solar cell of high efficiency and low cost.

Subsequently, a second electrode 120 may be formed on the quantum-graphine hybrid composite 110 (S5000).

Hereinafter, a method of manufacturing the quantum dot-graphine hybrid composite 110 will be described in more detail.

First, quantum dots combined with first ligands may be formed (S2000). In some embodiments, the quantum dots having the first ligands may be CdSe quantum dots combined with trioctylphosphine oxide (TOPO) ligands.

In more detail, a first solution may be formed (S200). The first solution may include selenium and a first solvent of phosphine series. The first solvent may include trioctylphosphine (TOP) and toluene. A second solution may be formed (S210). The second solution may include cadmium and a second solvent of phosphine series. For example, the second solution may include a solution including cadmium and the second solvent. The solution including cadmium may be cadmium acetate dihydrate and the second solvent may include trioctylphosphine oxide (TOPO). Gas may be removed from the second solution. Here, a color of the second solution may be yellow.

If the second solution is heated at a temperature within a range of about 280 degrees Celsius to about 300 degrees Celsius and the first solution is added into the second solution, the color of the second solution may be changed from the yellow to red. During the process, a desired size of the quantum dot may be determined using an instrument measuring a size of the quantum dot (S220 and S230). If the size of the quantum dot reaches the desired size, the mixed solution of the first and second solutions may be rapidly cooled. Subsequently, the CdSe quantum dots combined with the TOPO ligands may be separated from the mixed solution.

Graphine may be prepared (S3000). A method of forming the graphine will be described in more detail. First, graphite may be dissolved in an acidic solution to form an oxidized graphite. The acidic solution may include at least one of H₂SO₄, K₂S₂O₉, and P₂O₅. After the oxidized graphite is dissolved in sulfuric acid and KMnO₄, an oxygenated wafer (H₂O₂) may be added to the solution including the sulfuric acid and the KMnO₄ in which the oxidized graphite is dissolved. In this time, the solution may have a yellow color. Subsequently, after hydrochloric acid (HCl) is added to the solution having the yellow color, metal may be removed from the solution added with the hydrochloric acid by a centrifuge method. The color of the solution may be changed from the yellow color to a brown color. At this time, graphine oxide may be compounded (S300). N₂H₂ may be added to the graphine oxide, so that the graphine oxide may be reduced to form graphine (S310).

The CdSe quantum dots combined with the TOPO ligands and the graphine may be dispersed in a solution including second ligands (S400). In the present embodiment, the second ligand may be a pyridine ligand. Since the pyridine ligand is a bidentate ligand, the pyridine ligand has more excellent reactivity than the TOPO ligand. The pyridine ligand may be substituted for the TOPO ligand combined with the quantum dot.

The CdSe quantum dot having the pyridine ligand may be combined with the graphine in a π-bond (S4000). Subsequently, the pyridine may be removed from the CdSe quantum dot having the pyridine ligand π-bonded to the graphine by a centrifuge method (S410).

As described above, since the quantum dot of the quantum dot-graphine hybrid composite 110 is combined with the graphine in the π-bond, a bonding force between the quantum dot and the graphine is stronger and density of the quantum dot and the graphine is higher. Thus, the electrons generated from the quantum dot may be easily and quickly moved.

Additionally, the solar cell including the quantum dot-graphine hybrid composite 110 uses the quantum dots of low cost differently from a conventional solar cell including a high cost dye of ruthenium series and uses the graphine as a medium quickly transmitting electrons generated from the quantum dots. Thus, it is possible to reduce a manufacturing cost of the solar cell.

Furthermore, since a single-layered quantum dot-graphine hybrid composite 110 may be formed on the first electrode 100 by one-step, it is possible to form the quantum dot-graphine hybrid composite structure 235 including a multi-layered structure in FIG. 2.

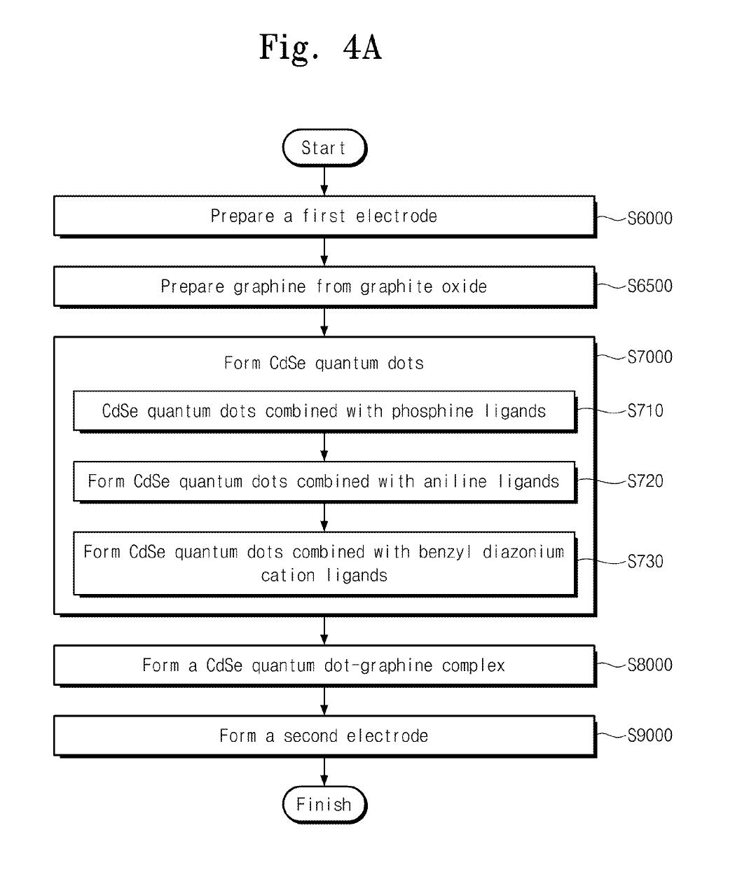

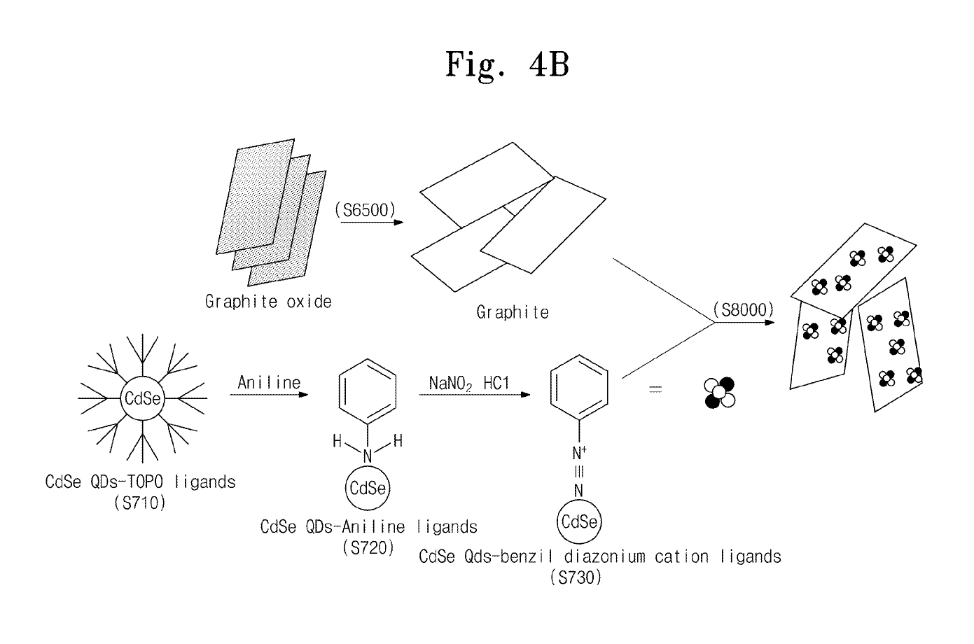

FIG. 4A is a flow chart illustrating a method of manufacturing a solar cell according to other embodiments of the inventive concept. FIG. 4B is a schematic diagram illustrating a method of manufacturing a solar cell according to other embodiments of the inventive concept.

Referring to FIGS. 1, 4A and 4B, a first electrode 100 may be prepared (S6000), a quantum dot-graphine hybrid composite 110 may be deposited on one surface of the first electrode 100 (S8000), and a second electrode 200 may be formed on the quantum dot-graphine hybrid composite 110 (S9000).

The method of forming the first electrode 100 and the method of forming the second electrode 120 may be substantially the same as the corresponding methods described with reference to FIG. 3. Additionally, the method of preparing the graphine from the graphite oxide may be the same as the corresponding methods described with reference to FIG. 3 (S6500). Thus, the description of the methods will be omitted.

A method of forming the quantum dot-graphine hybrid composite 110 according to the present embodiment is different from the method of forming the quantum dot-graphine hybrid composite 110 described with reference to FIG. 3. Hereinafter, the method of the quantum dot-graphine hybrid composite 110 according to the present embodiment will be described in more detail.

First, quantum dots combined with first ligands may be formed (S710). In some embodiments, the quantum dots having the first ligands may be CdSe quantum dots combined with trioctylphosphine oxide (TOPO) ligands. A method of forming the CdSe quantum dots combined with the TOPO ligands may be substantially the same as the corresponding method described with reference to FIG. 3. Thus, the description of the method will be omitted.

The CdSe quantum dots combined with the first ligands may be dispersed in a solution including second ligands, so that the second ligands may be substituted for the first ligands, thereby forming CdSe quantum dots combined with the second ligands (S720). In the present embodiment, the second ligand may be an aniline ligand. Substituting the TOPO ligand for the aniline ligand may be performed by refluxing the CdSe quantum dots having the first ligands in a toluene solution to which the aniline is added.

The CdSe quantum dots combined with the second ligands may be dispersed in a solution including third ligands, so that the third ligands may be substituted for the second ligands, thereby forming CdSe quantum dots combined with the third ligands (S730). The third ligand may be benzyl diazonium cation ligand. The process substituting the aniline ligand for the benzyl diazonium cation ligand at the CdSe quantum dot will be described briefly. After the CdSe quantum dots having the aniline ligands may be centrifuged by ethanol, the centrifuged CdSe quantum dots may be dispersed in dimethyl formamide. Subsequently, NaNO₂ and HCl may be added to the dimethyl formamide including the centrifuged CdSe quantum dots. Thus, the aniline ligands may be substituted for the benzyl diazonium cation ligands, thereby forming the CdSe quantum dots combined with the benzyl diazonium cation ligands.

Since the CdSe quantum dots combined with the benzyl diazonium cation ligands have positive charges, these may be easily deposited on a cathode by a subsequent electro-deposition process and be easily combined with graphine in the π-bond.

the CdSe quantum dots combined with the benzyl diazonium cation ligands may be combined with the graphine in a solution by the π-bond (S8000).

As described above, since the quantum dot of the quantum dot-graphine hybrid composite 110 is combined with the graphine in the π-bond, a bonding force between the quantum dot and the graphine is stronger and density of the quantum dot and the graphine is higher. Thus, the electrons generated from the quantum dot may be easily and quickly moved.

Additionally, since a single-layered quantum dot-graphine hybrid composite 110 may be formed on the first electrode 100 by one-step, it is possible to form the quantum dot-graphine hybrid composite structure 235 including a multi-layered structure in FIG. 2.

Hereinafter, the method of manufacturing the quantum dot-graphine hybrid composite will be described through experiment examples.

### Experiment Example 1

### 1. Formation of CdSe Quantum Dots Combined with POTO Ligands

A selenium solution of 0.4 g (gram) was mixed with 90%-TOP of 10 mL and toluene of 0.2 mL, so that a first solution was formed.

90%-TOPO of 20 g was mixed with cadmium acetate dehydrate of 0.25 g and then the mixture was heated to 150 degrees Celsius. Thus, a second solution was formed. A gas was removed from the second solution during 20 minutes. And the second solution was heated at a temperature within a range of 280 degrees Celsius to 300 degrees Celsius. At this time, the color of the second solution was yellow.

The first solution was added to the second solution which was being heated at the temperature within a range of 280 degrees Celsius to 300 degrees Celsius, so that the color of the second solution was being changed into red. While the color of the second solution was being changed into red, the CdSe quantum dots combined with POTO ligands and having the desired sizes were obtained using a US-Vis spectrometer. When the CdSe quantum dots combined with POTO ligands and having the desired sizes appeared, the heating the mixed solution of the first and second solutions was stopped. And then the mixed solution was cooled at 50 degrees Celsius.

The CdSe quantum dots combined with the POTO ligands were precipitated using ethanol from the mixed solution of the first and second solutions. The mixed solution further including the ethanol was melted by toluene. The precipitating the CdSe quantum dots combined with the POTO ligands was repeated three times or more.

### 2. Graphine Oxide and Manufacture of Graphine

Graphite powder having 325-mesh of 20 g was mixed with concentrated sulfuric acid of 30 mL, K₂S₂O₈ of 10 g, and P₂O₂ of 10 g at 80 degrees Celsius, so that a first solution was formed. The first solution was reacted at a room temperature for 6 hours. The first solution was washed several times by deionized water with filtering until a pH of the first solution became neutral. And then the washed first solution was drying at an ambient temperature for one day. Thus, oxidized graphite powder was obtained.

The oxidized graphite powder of 20 g was added to concentrated sulfuric acid at 0 degree Celsius and then KMnO₄ of 60 g was slowly added to the concentrated sulfuric acid including the oxidized graphite power at a temperature of 20 degrees Celsius or less. Thus, a second solution was formed. The second solution was being stirred at 35 degrees Celsius for 2 hours.

Deionized water of 920 mL was added to the second solution. After 15 minutes, deionized wafer of 2.8 L and 30%-H₂O₂ of 50 mL were further added to the mixed solution of the second solution and the deionized wafer of 920 mL. Thereafter, a color the mixed solution including the second solution was changed into a bright yellow color.

The solution having the bright yellow color was filtered and washed using 10%-HCl of 5 L. Thus, metal ions were removed from the solution having the bright yellow color. Subsequently, the solution from which the metal ions were removed was centrifuged to form graphine oxide having a brown color.

The graphine oxide of 10 mg was dispersed in deionized water of 20 mL and then N₂H₄ of 2 mL was added to the deionized wafer including the graphine oxide. Thus, the graphine oxide was reduced to form graphine. The N₂H₄ was added at 90 degrees Celsius in order that the reduced graphine did not aggregate.

### 3. Formation of CdSe Quantum Dots-Graphine Hybrid Composite

The CdSe quantum dots combined with the POTO ligands of 60 mg and the graphine was dispersed in pyridine and then the CdSe quantum dots combined with the POTO ligands and the graphine dispersed in pyridine were refluxed at 60 degrees Celsius for one day. During the refluxing, pyridine ligands were substituted for the POTO ligands of the CdSe quantum dots, and the CdSe quantum dots combined with the pyridine ligands were combined with the graphine in the π-bond.

The pyridine was removed from the CdSe quantum dots combined with the graphine in the π-bond by the centrifuge method. Thus, the CdSe quantum dot-graphine hybrid composite was formed. The CdSe quantum dot-graphine hybrid composite was dispersed in tetrahydrofuran (THF).

### Experiment Example 2

1. Forming CdSe quantum dots combined with POTO ligands

The method of forming CdSe quantum dots combined with POTO ligands was the same as the Experiment example 1.

2. Forming CdSe quantum dots combined with aniline ligands from CdSe quantum dots combined with POTO ligands

The CdSe quantum dots combined with POTO ligands were being refluxed in toluene added with aniline for 24 hours.

3. Forming benzyl CdSe quantum dots combined with diazonium cation ligands from CdSe quantum dots combined with aniline ligands

The CdSe quantum dots combined with aniline ligands were centrifuged using ethanol and then it was dispersed in dimethyl formamide. Thereafter, NaNO₂ of 20 mM (millimole) and HCl of 20 mM were added to the dimethyl formamide including the centrifuged CdSe quantum.

4. Graphine oxide and manufacture of graphine

A method of manufacturing graphine oxide and graphine was the same as the Experiment example 1.

5. Forming CdSe quantum dot-graphine hybrid composite

The graphine was put into the solution 3 including the CdSe quantum dots combined with diazonium cation ligands and then an electro-deposition process was performed to combine the CdSe quantum dots with the graphine in the π-bond.

### Experiment Result

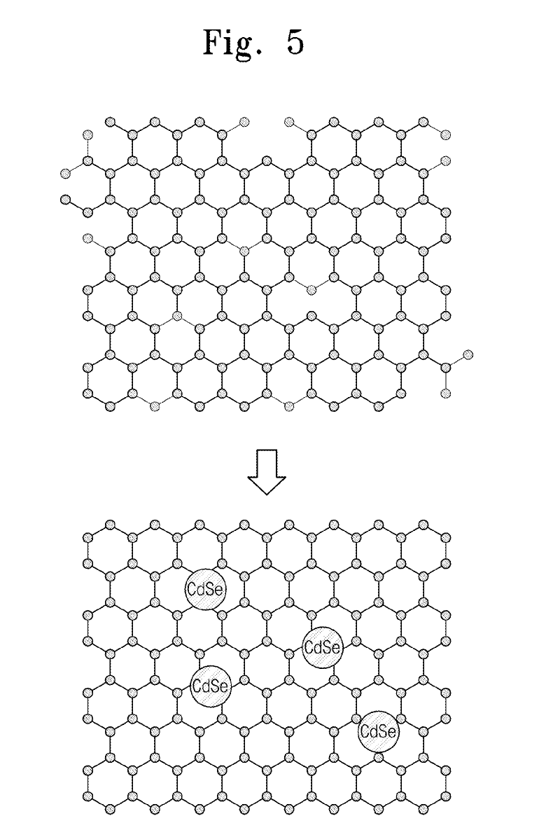

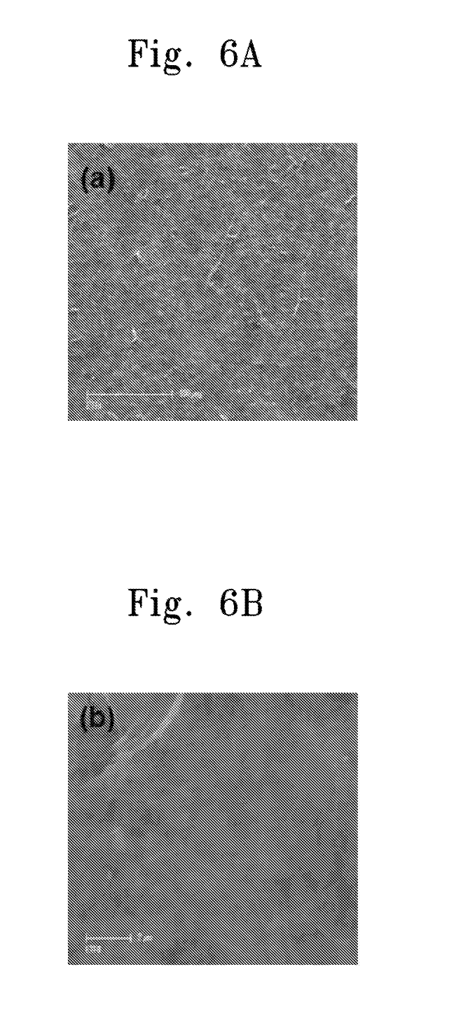

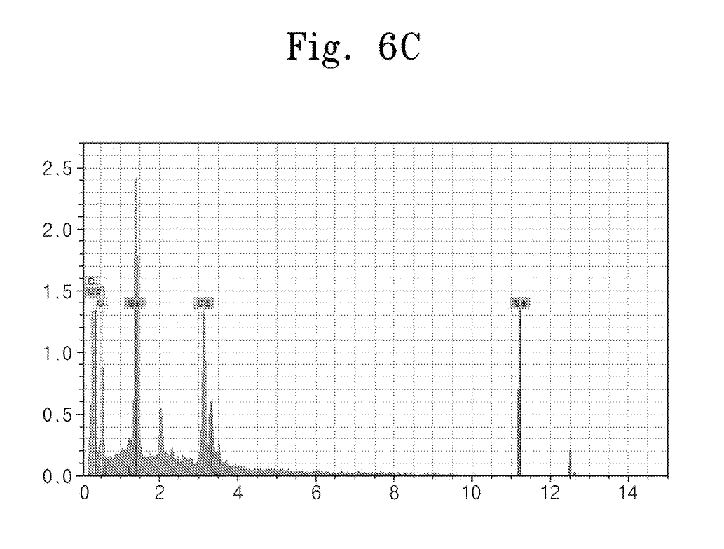

FIG. 5 shows molecule structural formulas to explain chemical reaction of graphine formed by reducing graphine oxide and graphine combined with CdSe quantum dots. FIGS. 6A and 6B are photographs of a surface graphine combined with CdSe quantum dots. FIG. 6C is a graph illustrating components of graphine combined with CdSe quantum dots.

An upper molecule structural formula of FIG. 5 shows graphine oxide. If N2H4 reducing agent and the CdSe quantum dots combined with pyridine ligands are added to the graphine oxide, the CdSe quantum dot-graphine hybrid composite having a lower molecule structural formula of FIG. 5 is formed.

FIGS. 6A and 6B show CdSe quantum dots directly combined with the graphine. That is, FIGS. 6A and 6B show the CdSe quantum dot-graphine hybrid composite having the lower molecule structural formula of FIG. 5. In other words, the CdSe quantum dots are combined with the graphine in the π-bond, so that the bonding force between the CdSe quantum dots and the graphine is stronger. Additionally, since the CdSe quantum dot-graphine hybrid composite is combined with the electrode by electrophoresis, the bonding force between the CdSe quantum dots and the electrode is also stronger.

Referring to FIG. 6C, selenium (Se) cadmium (Cd), carbon (C), and oxygen (O) are detected by a component-detecting process. Thus, it is confirmed that the surfaces of FIGS. 6A and 6B are the CdSe quantum dot-graphine hybrid composites.

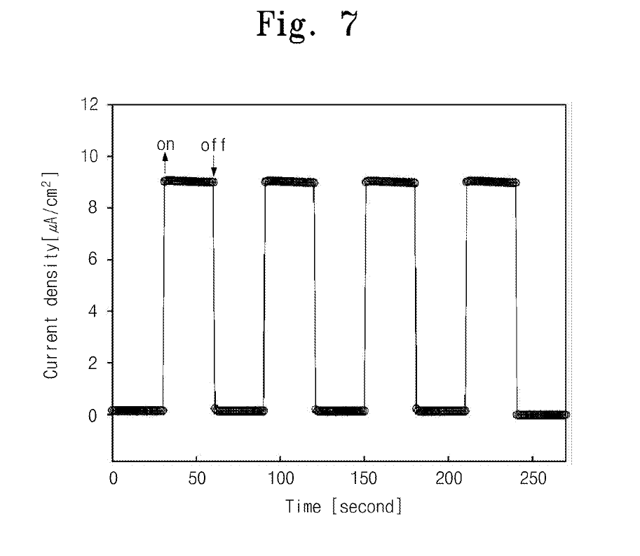

FIG. 7 is a graph illustrating reaction of current density of a solar cell according to some embodiments of the inventive concept.

The graph of FIG. 7 shows reaction of current density according to cycles repeatedly turning on/off light to the solar cell. An x-axis represents a time (second) and a y-axis represents the current density (μA/cm²).

The solar cell includes a first electrode a quantum dot-graphine hybrid composite, and a second electrode. The solar cell is substantially the same as the solar cell described with reference to FIG. 1.

As illustrated in FIG. 7, the variation amount of the current density of the solar cell according to the inventive concept is about 9 μA/cm² in the on-off cycle. However, a variation amount of a current density of a conventional solar cell may be about 4 μA/cm'. Thus, the variation amount of the current density of the solar cell according to the inventive concept is about 2 times greater than that of a conventional solar cell.

According to embodiments of the inventive concept, the quantum dot-graphine hybrid composite is applied to the solar cell. Due to the graphine with high conductivity, electrons and holes may be rapidly separated from each other, recombination of the electrons and holes may be reduced or prevented, and an optical current may be improved. Particularly, electrons generated at the quantum dots may be rapidly transmitted through the graphine, so that efficiency of the solar cell may be maximized. Additionally, the solar cell with high efficiency may be manufactured in low cost by the quantum dot-graphine hybrid composite.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A solar cell comprising:
a first electrode;
a second electrode facing and separated from the first electrode; and
a quantum dot-graphine hybrid composite disposed between the first and second electrodes,
wherein quantum dots are combined with graphine in a π-bond within the quantum dot-graphine hybrid composite.

2. The solar cell of claim 1, wherein the quantum dot-graphine hybrid composite includes cadmium selenide (CdSe)-graphine.

3. The solar cell of claim 1, wherein the quantum dot-graphine hybrid composite comprises:
a first quantum dot-graphine including a quantum dot of a first size; and
a second quantum dot-graphine including a quantum dot of a second size different from the first size,
wherein the quantum dot-graphine and the second quantum dot-graphine are sequentially stacked.

4. The solar cell of claim 1, wherein the first and second electrodes include a transparent and flexible material.

5. A method of manufacturing a solar cell, comprising:
preparing a first electrode;
forming quantum dots combined with ligands;
combining the quantum dots combined with ligands with graphine in a π-bond to form a quantum dot-graphine hybrid composite;
depositing the quantum dot-graphine hybrid composite on the first electrode; and
forming a second electrode on the quantum dot-graphine hybrid composite.

6. The method of claim 5, wherein forming the quantum dots combined with ligands comprises:
dissolving selenium in a solvent of phosphine series to form a first solution;
dissolving cadmium in a solvent of phosphine series to form a second solution; and
mixing the first solution into the second solution to form CdSe quantum dots combined with phosphine ligands.

7. The method of claim 6, wherein forming the CdSe quantum dots combined with phosphine ligands comprises:
heating the second solution;
adding the first solution to the second solution for heating the second solution; and
stopping heating the second solution when sizes of CdSe quantum dots become desired sizes.

8. The method of claim 6, wherein forming the quantum dot-graphine hybrid composite comprises:
dispersing the CdSe quantum dots combined with the phosphine ligands and the graphine in pyridine;
substituting pyridine ligands for the phosphine ligands to form CdSe quantum dots having the pyridine ligands;
combining the CdSe quantum dots with the graphine in the π-bond to form a CdSe quantum dot-graphine hybrid composite including the pyridine ligands; and
removing the pyridine ligands from the CdSe quantum dot-graphine hybrid composite including the pyridine ligands.

9. The method of claim 5, wherein forming the quantum dots combined with the ligands comprises:
preparing quantum dots combined with phosphine ligands;
dispersing the quantum dots combined with phosphine ligands in a pyridine solution; and
substituting pyridine ligands for the phosphine ligands to form quantum dots combined with the pyridine ligands.

10. The method of claim 5, wherein the quantum dot-graphine hybrid composite is formed on the first electrode by electrophoresis or a printing process.

11. The method of claim 6, wherein forming the quantum dot-graphine hybrid composite further comprises:
substituting aniline ligands for the phosphine ligands of the CdSe quantum dots combined with the phosphine ligands, thereby forming CdSe quantum dots combined with the aniline ligands; and
substituting benzyl diazonium cation ligands for the aniline ligands of the CdSe quantum dots combined with the aniline ligands, thereby forming CdSe quantum dots combined with the benzyl diazonium cation ligands.

12. The method of claim 11, wherein forming the quantum dot-graphine hybrid composite further comprises:
dispersing the graphine and the CdSe quantum dots combined with the benzyl diazonium cation ligands in a mixed solution of dimethyl formamide. NaNO₂ and HCl; and
forming CdSe quantum dot-graph hybrid composite in the mixed solution by an electro-deposition process.
